(19) United States
(12) Patent Application Publication
(10) Pub. No.: US 2015/0268276 A1
(43) Pub. Date: Sep. 24, 2015

(54) PROBE CABLE AND HARNESS USING THE SAME

(71) Applicant: Hitachi Metals, Ltd., Tokyo (JP)

(72) Inventors: Detian HUANG, Hitachi (JP); Takanobu WATANABE, Hitachi (JP); Kimika KUDO, Kitaibaraki (JP)

(21) Appl. No.: 14/625,264

(22) Filed: Feb. 18, 2015

(30) Foreign Application Priority Data
Mar. 24, 2014 (JP) 2014-059961

(51) Int. Cl. G01R 1/18; G01R 1/067

(52) U.S. Cl. CPC G01R 1/18; G01R 1/067

(57) ABSTRACT

A probe cable includes at least one core unit including a plurality of signal transmission coaxial wires being twisted together, and a sheath layer formed covering the core unit. The coaxial wires each include a center conductor, and an insulation layer and a shield sequentially formed on an outer periphery of the center conductor. The shield includes a metal tape including a metal layer on one surface of a resin layer, the metal tape being formed by being wound around the insulation layer such that the metal layer is located outside. The shield of the coaxial wires in the core unit contacts with each other.

The present application is based on Japanese patent application No. 2014-059961 filed on Mar. 24, 2014, the entire contents of which are incorporated herein by reference.

### BACKGROUND OF THE INVENTION

1. Field of the Invention

The invention relates to a probe cable used for ultrasonographs etc. and a harness using the probe cable.

2. Description of the Related Art

A single round type cable is known as a probe cable used in ultrasonographs, which is provided with plural core units each formed by twisting plural signal transmission coaxial wires, a binding tape for bundling the plural core units and a braided shield and a sheath layer provided in this order on the outer periphery of the binding tape.

In the probe cable, a served shield formed by spirally winding plural copper strands is generally used as a shield (outer conductor) of the coaxial wire.

The related art to the invention may include e.g. JP-A-H08-77835 and JP-A-H08-77836.

### SUMMARY OF THE INVENTION

In recent years, the number of coaxial wires used in the probe cable increases in order to improve the resolution.

However, the increase in the number of coaxial wires may cause an increase in thickness and weight of the probe cable since a metal component of the served shield increases thereby.

The probe cable is generally as long as 2.2 to 3 m. Thus, the increase in weight of the probe cable may cause a significant lowering in the operability when it is operated.

Also the increase in thickness of the probe cable may cause the difficulty in bending so as to further lower the operability.

It is an object of the invention to provide a lightweight and flexible probe cable as well as a harness using the probe cable.

(1) According to one embodiment of the invention, a probe cable comprises:
at least one core unit comprising a plurality of signal transmission coaxial wires being twisted together; and
a sheath layer formed covering the core unit,
wherein the coaxial wires each comprise a center conductor, and an insulation layer and a shield sequentially formed on an outer periphery of the center conductor, wherein the shield comprises a metal tape comprising a metal layer on one surface of a resin layer, the metal tape being formed by being wound around the insulation layer such that the metal layer is located outside, and
wherein the shield of the coaxial wires in the core unit contacts with each other.

In the above embodiment (1) of the invention, the following modifications and changes can be made.
(i) The coaxial wires each comprise a resin tape wound around the insulation layer and the metal tape wound around the resin tape, and wherein the resin tape and the metal tape are adhesively bonded by an adhesive layer provided on one or both of the resin tape and the metal tape.
(ii) The metal layer of the metal tape comprises aluminum.
(iii) The core unit further comprises a drain wire that is twisted together with the plurality of coaxial wires so as to contact with the shield of the plurality of coaxial wires.

(2) According to another embodiment of the invention, a harness comprises:
the probe cable according to the embodiment (1); and
a terminal component on at least one end portion of the probe cable.

### Effects of the Invention

According to one embodiment of the invention, a lightweight and flexible probe cable can be provided as well as a harness using the probe cable.

### BRIEF DESCRIPTION OF THE DRAWINGS

Next, the present invention will be explained in more detail in conjunction with appended drawings, wherein:

FIG. 1A is a cross sectional view showing a probe cable in an embodiment of the present invention;

FIG. 1B is a cross sectional view showing a coaxial wire;

FIG. 1C is an explanatory diagram showing bonding between a metal tape and a resin tape; and

FIG. 2 is an illustration of a harness using the cable of FIG. 1A.

### DETAILED DESCRIPTION OF THE PREFERRED EMBODIMENT

An embodiment of the invention will be described below in conjunction with the appended drawings.

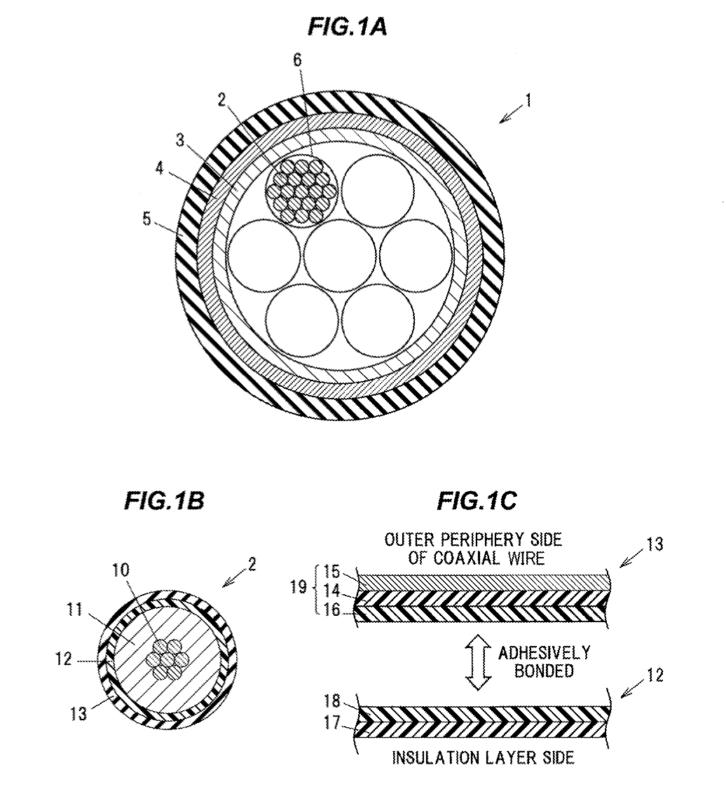

FIG. 1A is a cross sectional view showing a probe cable in the present embodiment, FIG. 1B is a cross sectional view showing a coaxial wire and FIG. 1C is an explanatory diagram illustrating bonding between a metal tape and a resin tape

As shown in FIG. 1A, a probe cable 1 has at least one or more core units 6 each formed by twisting plural signal transmission coaxial wires 2 together and a sheath layer 5 formed to cover the core units 6. The probe cable 1 is used for connecting, e.g., a main unit to a probe in an ultrasonograph. The total number of the coaxial wires 2 used in the probe cable 1 is, e.g., not less than one hundred.

In the present embodiment, seven core units 6 are bundled by a binding tape 3, and a braided shield 4 and the sheath layer 5 are sequentially provided on the outer periphery of the binding tape 3. However, the number of the core units 6 is not limited thereto. The core units 6 may additionally include an insulated wire for power supply.

The binding tape 3 is a resin tape for bundling plural core units 6 and it is possible use, e.g., a PTFE (polytetrafluoroethylene) tape.

The braided shield 4 is formed by braiding plural strands. Tinsel copper, which is less likely to be broken when being bent, is desirably used as strands used to form the braided shield 4. The tinsel copper here is a strand formed by spirally winding a copper foil around a center thread formed of polyester or aramid, etc.

The sheath layer 5 is formed of a medical insulating resin. The medical insulating resin, also called medical resin or medical grade resin, is a biocompatible (highly biologically compatible) resin which is non-toxic and does not cause allergic symptoms such as inflammation upon contact with living organisms. In the present embodiment, a medical grade PVC (polyvinyl chloride) is used as the medical insulating resin to form the sheath layer 5.

As shown in FIG. 1B, the coaxial wire 2 is formed by sequentially providing an insulation layer 11 and a shield 13 on an outer periphery of a center conductor 10.

The center conductor 10 is formed by twisting plural strands formed of highly conductive copper, aluminum or an alloy thereof. The strands may be plated with tin, silver or nickel, etc.

The insulation layer 11 is formed of a fluoropolymer such as tetrafluoroethylene-perfluoroalkyl vinyl ether copolymer (PFA), tetrafluoroethylene-hexafluoropropylene copolymer (FEP) or ethylene-tetrafluoroethylene copolymer (ETFE). A dielectric constant and a dielectric loss tangent of the fluoropolymer are small. Therefore, it is possible to suppress an increase in dielectric loss by using the fluoropolymer as a material of the insulation layer 11.

In the probe cable 1 of the present embodiment, the shield 13 of the coaxial wire 2 is formed of a metal tape 19 having a metal layer 15 on a surface of a resin layer 14 and is formed by winding the metal tape 19 around the insulation layer 11 so that the metal layer 15 is located on the outer side, as shown in FIGS. 1B and 1C.

In the present embodiment, the coaxial wire 2 is formed by winding a resin tape 12 around the insulation layer 11 and then winding the metal tape 19 around the resin tape 12, such that the resin tape 12 and the metal tape 19 are adhesively bonded by an adhesive layer(s) provided on one or both of the resin tape 12 and the metal tape 19.

In the present embodiment, the metal tape 19 is composed of the resin layer 14, the metal layer 15 formed on a surface of the resin layer 14 and an adhesive layer 16 formed on another surface of the resin layer 14, the resin tape 12 is composed of a resin layer 17 and an adhesive layer 18 formed on a surface thereof, and the adhesive layers 16 and 18 of the two tapes 12 and 19 are adhered to adhesively bond the resin tape 12 to the metal tape 19.

The resin tape 12 is wound around the insulation layer 11 so that the adhesive layer 18 is located on the outer side. The resin tape 12 is spirally wound in a partially overlapping manner.

The metal tape 19 is wound around the resin tape 12 so that the metal layer 15 is located on the outer side and the adhesive layer 16 on the inner side. The metal tape 19 is spirally wound in a partially overlapping manner.

The adhesive layers 16 and 18 are preferably formed of a heat-seal adhesive. After winding the resin tape 12 and the metal tape 19, the two adhesive layers 16 and 18 are adhered to each other by heating and the resin tape 12 is thereby adhesively bonded to the metal tape 19.

By adhesively bonding the resin tape 12 to the metal tape 19 using the adhesive layers 16 and 18, the two tapes 12 and 19 are integrated and form a pipe-shaped structure. Therefore, defects such as separation of the metal tape 19 at the time of bending the probe cable 1 can be reduced as compared to the case of using only the metal tape 19.

In addition, since the pipe-shaped structure formed by integrating the two tapes 12 and 19 is not adhesively bonded to the insulation layer 11 and is slidable in a longitudinal direction of the cable, stress applied to the insulation layer 11 or the center conductor 10 at the time of bending the probe cable 1 is dispersed and it is thus possible to improve flex resistance.

The metal layer 15 of the metal tape 19 is desirably formed of aluminum which is light in weight and highly conductive. Aluminum is suitable as the metal layer 15 since an oxide film produced on a surface thereof prevents corrosion or discoloration even if exposed to outside air, which allows desired electrical characteristics to be maintained for a long period of time even without providing a jacket and good appearance to be kept.

The metal tape 19 used in the present embodiment is an AL/PET tape in which the metal layer 15 of aluminum is formed on one of surfaces of the resin layer 14 of PET (polyethylene terephthalate) and the adhesive layer 16 is formed on another surface of the resin layer 14. Meanwhile, the resin tape 12 used here is a PET tape in which the adhesive layer 18 is formed on a surface of the resin layer 17 of PET.

The aluminum metal layer 15 of the metal tape 19 is desirably not less than 7 μm and not more than 13 μm in thickness. This is because, when the thickness of the metal layer 15 is less than 7 μm, conductor resistance becomes high, causing an increase in loss.

On the other hand, flexibility decreases when more than 13 μm.

Meanwhile, the PET resin layer 14 of the metal tape 19 is desirably not less than 4 μm and not more than 6 μm in thickness. This is because the resin layer 14 is likely to be broken when the thickness of the resin layer 14 is less than 4 μm. On the other hand, when more than 6 μm, the entire metal tape 19 becomes thick, a level difference at an overlapping portion thereof becomes large and interferes with level differences of the coaxial wires 2 therearound when being bent and this may cause defects such as breakage.

A polyester-based heat-seal adhesive, which has high adhesiveness to PET used to form the resin layers 14 and 17 in the present embodiment, is preferably used to form the adhesive layers 16 and 18. Use of the same material to form the adhesive layers 16 and 18 allows for more firm adhesive bonding.

In the probe cable 1, the outermost layer of the coaxial wire 2 is the metal layer 15 of the metal tape 19 and the coaxial wire 2 does not have a jacket formed of an insulating material. Therefore, when the plural coaxial wires 2 are bundled to form the core unit 6, the shields 13 (the metal layers 15) of the plural coaxial wires 2 constituting the core unit 6 come into contact with each other and are electrically conducted to each other.

When there is only one coaxial wire 2, it is considered that transmission loss increases in the thin metal layer 15. In contrast, in the core unit 6, since the metal layers 15 of plural coaxial wires 2 are electrically conducted to each other and serve as one shield, a shielding conductor has an enough cross sectional area and an increase in transmission loss can be thereby suppressed.

In case of using the metal layers 15 formed of aluminum, it is preferable to separately provide a drain wire for grounding since aluminum is difficult to solder and thus makes end processing difficult. In case of providing a drain wire, the core unit 6 is configured such that the drain wire is twisted together with the coaxial wires 2 so as to be in contact with the shields 13 (the metal layers 15) of the coaxial wires 2. A stranded conductor formed by twisting plural metal strands is preferably used as the drain wire to prevent wire breakage at the time of being bent.

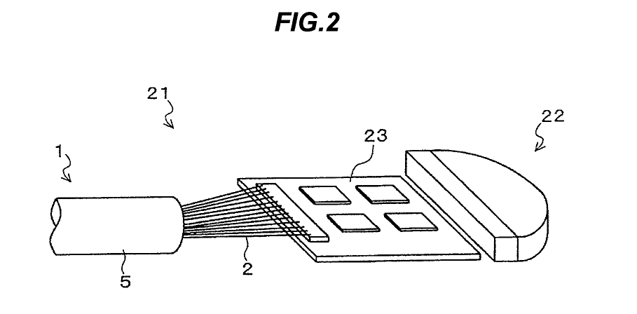

As shown in FIG. 2, a harness 21 in the present embodiment is composed of the probe cable 1 in the present embodiment and a probe head 22 as a terminal component provided on at least one of end portions of the probe cable 1. The coaxial wires 2 of the probe cable 1 are connected to a circuit board 23 which comprises a PCB (printed circuit board) or a FPC (flexible printed circuit) and is located inside the probe head 22. In case that the drain wire is provided, an end of the drain wire is connected to a ground pattern of the circuit board 23.

Although the terminal component of the probe cable 1 is described as the probe head 22 in the present embodiment, it is not limited thereto. The terminal component may be configured to have, e.g., only the circuit board 23 such as PBC or FPC or may be a connecter used for connection to the probe head 22 or to a main unit of an ultrasonograph.

As described above, the probe cable 1 in the present embodiment is configured that the shield 13 of the coaxial wire 2 is formed of the metal tape 19 having the metal layer 15 on a surface of the resin layer 14 and is formed by winding the metal tape 19 around the insulation layer 11 so that the metal layer 15 is located on the outer side, and the shields 13 of the plural coaxial wires 2 constituting the core unit 6 are in contact with each other.

In the probe cable 1 provided with a number of coaxial wires 2, if the shield 13 of each coaxial wire 2 is heavy, the weight of the entire probe cable 1 increases significantly.

In the present embodiment, the metal tape 19 is used to form the shield 13 of the coaxial wire 2 and this allows the weight of the probe cable 1 to be reduced as compared to a conventional art using a served shield formed by spirally winding plural copper strands.

When reducing the thickness of the shield 13, there is concern of an increase in transmission loss due to an increase in resistance in the shield 13. However, in the probe cable 1, the shields 13 of the plural coaxial wires 2 constituting the core unit 6 are in contact with each other and serve as one shield of the entire core unit 6, the shield has an enough cross sectional area and an increase in transmission loss is thus suppressed.

In addition, the shields 13 of the coaxial wires 2 are electrically conducted throughout the length of the probe cable 1. Therefore, a potential difference is not locally generated between the shields 13 of the coaxial wires 2 and it is thus possible to suppress crosstalk.

Furthermore, in the probe cable 1, the thin metal tape 19 is used to form the shield 13 and a jacket is not provided on the coaxial wire 2. This allows the diameter of the probe cable 1 to be reduced and it is thus possible to easily realize a bendable and flexible probe cable 1.

In addition, unlike the conventional cable using a served shield in which copper strands are fractured and broken due to bending fatigue, there is no such a risk in the probe cable 1 since the metal tape 19 is used to form the shield 13 of the coaxial wire 2 and flex life of the probe cable 1 is thus long. In addition, it is possible to omit work of producing and winding very thin copper strands unlike the conventional technique, it is possible to form the shield 13 only by winding the metal tape 19 and it is also possible to eliminate a jacket manufacturing process. Therefore, it is easy to manufacture at low cost.

The invention is not intended to be limited to the embodiment, and it is obvious that the various kinds of modification can be implemented without departing from the gist of the invention.

For example, although the probe cable 1 used in an ultrasonograph has been described in the embodiment, the use of the present invention is not limited thereto.

What is claimed is:

1. A probe cable, comprising:
at least one core unit comprising a plurality of signal transmission coaxial wires being twisted together; and
a sheath layer formed covering the core unit,
wherein the coaxial wires each comprise a center conductor, and an insulation layer and a shield sequentially formed on an outer periphery of the center conductor,
wherein the shield comprises a metal tape comprising a metal layer on one surface of a resin layer, the metal tape being formed by being wound around the insulation layer such that the metal layer is located outside, and
wherein the shield of the coaxial wires in the core unit contacts with each other.

2. The probe cable according to claim 1, wherein the coaxial wires each comprise a resin tape wound around the insulation layer and the metal tape wound around the resin tape, and
wherein the resin tape and the metal tape are adhesively bonded by an adhesive layer provided on one or both of the resin tape and the metal tape.

3. The probe cable according to claim 1, wherein the metal layer of the metal tape comprises aluminum.

4. The probe cable according to claim 1, wherein the core unit further comprises a drain wire that is twisted together with the plurality of coaxial wires so as to contact with the shield of the plurality of coaxial wires.

5. A harness, comprising:
the probe cable according to claim 1; and
a terminal component on at least one end portion of the probe cable.
